(19) United States
(12) Patent Application Publication
(10) Pub. No.: US 2021/0002434 A1
(43) Pub. Date: Jan. 7, 2021

(54) RESIN POWDER, SEALING MATERIAL, ELECTRONIC COMPONENT, AND RESIN POWDER MANUFACTURING METHOD

(71) Applicant: Panasonic Intellectual Property Management Co., Ltd., Osaka (JP)

(72) Inventors: Takanori TSUZUKI, Nara (JP); Junichi TAKASHIRO, Osaka (JP); Daizou BABA, Hyogo (JP)

(73) Assignee: Panasonic Intellectual Property Management Co., Ltd., Osaka (JP)

(21) Appl. No.: 16/981,479

(22) PCT Filed: Mar. 18, 2019
(86) PCT No.: PCT/JP2019/011071

§ 371 Date: Sep. 16, 2020

(30) Foreign Application Priority Data
Apr. 2, 2018 (JP) 2018-071132
Apr. 2, 2018 (JP) 2018-071134

(51) Int. Cl. C08J 3/12; C08L 63/00; C08L 79/08; H01L 23/29

(52) U.S. Cl. CPC C08J 3/12; C08L 63/00; C08L 79/08; H01L 23/295; C08L 2203/20; C08J 2379/08; C08J 2463/00; C08J 2479/08; C08L 2205/025; C08J 2363/00

(57) ABSTRACT

Resin powder includes aggregates of spherical particles of a resin composition. The resin composition contains: a resin component including a thermosetting resin; and a non-resin component including at least one electrically insulative inorganic particle and/or at least one magnetic particle.

### TECHNICAL FIELD

The present disclosure generally relates to resin powder, sealing materials, electronic components, and resin powder manufacturing methods and specifically, to resin powder for use in an electronic component, a sealing material, the electronic component, and a resin powder manufacturing method.

### BACKGROUND ART

Along with higher functionality and further miniaturization of digital household appliance and the like, a compression molding method has been used as a resin seal technique of semiconductor elements. In the compression molding method, a sealing material is directly inserted into a cavity formed in a mold, and pressure is applied such that a melted resin composition is slowly pressed against a semiconductor element, thereby performing molding.

Patent Literature 1 discloses a granular semiconductor sealing resin composition (hereinafter referred to as a granular resin composition) as the sealing material adopted in the compression molding method. The granular resin composition is produced as described below. First of all, a thermosetting resin, a curing agent, inorganic fillers, a curing accelerator, and an additive are premixed with a Henschel mixer, are put in a twin-shaft kneader hopper, and are then melt-kneaded at a resin composition temperature of 100° C. with a twin-shaft kneader and extruded from a T die installed at an extruder tip end into a rectangular column shape. A rectangular column-shaped composition which has been cooled is put in a hopper of a pulverization-type granulator and is cut with a plurality of knives of the pulverization-type granulator, thereby performing particle size regulation. The granular resin composition is thus obtained.

Since the granular resin composition described in Patent Literature 1 is obtained by granulation with the pulverization-type granulator, particles included in the granular resin composition each has an angular fragment shape. Therefore, when the granular resin composition are handled, for example, are put in the cavity formed in the mold, friction of the particles is caused, thereby producing fine particles, scattering of which may resulting in contamination of facilities and/or troubles in measurement. Moreover, since the granular resin composition is bulky, the granular resin composition may not be uniformly put in the cavity formed in the mold, and a sealing resin obtained by melting and then curing the granular resin composition may have poor appearance.

Patent Literature 2 describes, as one of conditions for obtaining satisfactory characteristics of a powder magnetic core at a high frequency, that the electric resistance of metal magnetic powder is increased and the dimension of particles of the metal magnetic powder is optimized, thereby reducing an eddy current in the particles of the metal magnetic powder. The powder magnetic core is obtained by, for example, mixing the metal magnetic powder with an insulating organic binder to obtain a mixture, press-molding the mixture, and optionally heat-curing the organic binder.

However, when the particles of the magnetic powder is atomized to reduce the eddy current in the particles of the metal magnetic powder, scattering of fine particles is likely to cause contamination of facilities, troubles in measurement, and the like, and therefore, the metal magnetic powder has to be carefully handled.

### CITATION LIST

### Patent Literature

Patent Literature 1: JP 2015-116768 A

Patent Literature 2: JP H09-102409 A

### SUMMARY OF INVENTION

It is an object of the present disclosure to provide resin powder which is easily handled, a sealing material, an electronic component, and a resin powder manufacturing method.

Resin powder according to one aspect of the present disclosure includes aggregates of spherical particles of a resin composition. The resin composition contains: a resin component including a thermosetting resin; and a non-resin component including at least one electrically insulative inorganic particle and/or at least one magnetic particle.

A sealing material according to one aspect of the present disclosure includes the resin powder.

An electronic component according to one aspect of the present disclosure includes a molded body including the resin powder.

A resin powder manufacturing method according to one aspect of the present disclosure includes preparing slurry, and granulating the slurry by a spray-dry method. The slurry contains: a resin component including a thermosetting resin; and a non-resin component including at least one electrically insulative inorganic particle and/or at least one magnetic particle.

### BRIEF DESCRIPTION OF DRAWINGS

FIG. 1 is a scanning electron microscope (SEM) image (magnification: 100 times) of resin powder obtained in Example 1-1;

FIG. 2A is a graph illustrating number particle size distribution of the resin powder obtained in Example 1-1, and FIG. 2B is a graph of volume particle size distribution of the resin powder obtained in Example 1-1;

FIG. 3A is a graph of an aspect ratio of the resin powder obtained in Example 1-1, and FIG. 3B is a graph of a circularity of the resin powder obtained in Example 1-1;

FIG. 4A is an image of a sample of Example 1-1, and FIG. 4B is an image of a sample of Comparative Example 1-1; and

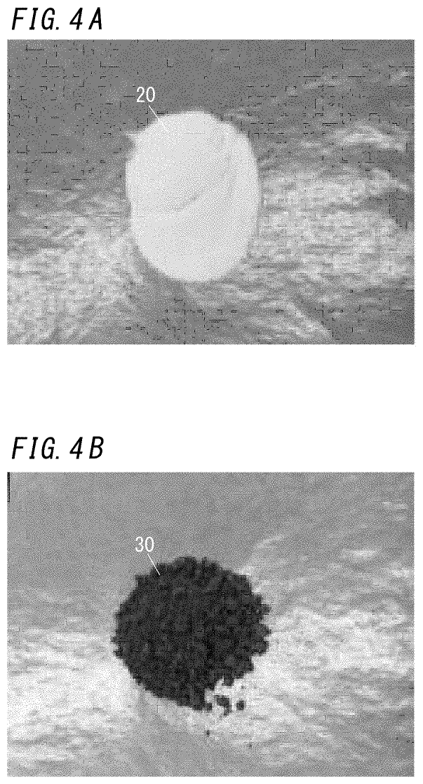

FIG. 5A is an image of a sample in a test tube in Example 1-1 and a sample in a test tube in Comparative Example 1-2 after bottom surfaces of the respective test tube are tapped three times, and FIG. 5B is an enlarged image of the sample in the test tube in Example 1-1 and the sample in the test tube in Comparative Example 1-2 of FIG. 5A, wherein in FIGS. 5A and 5B, a sample on the left is the sample in Example 1-1, and a sample on the right is the sample in Comparative Example 1-2.

### DESCRIPTION OF EMBODIMENTS

The embodiments will be described below based on the drawings. Note that the embodiments described below is a mere example of various embodiments of the present disclosure. Various modifications may be made to the following embodiments depending on design and the like as long as the object of the present disclosure is achieved.

### First Embodiment

(1) Resin Powder

Resin powder of the present embodiment (hereinafter referred to as resin powder) includes aggregates of spherical particles of a resin composition. The resin composition contains a resin component and a non-resin component (in the present embodiment, electrically insulative inorganic particles).

As used herein, “spherical” means that the average circularity of the resin powder is greater than or equal to 0.90 and the average aspect ratio of the resin powder is greater than or equal to 0.80. The average circularity is an average value of circularities of the spherical particles and is obtainable in a similar manner to the method described in the examples. The circularity is synonymous with “Circularity” defined by ISO 9276-6. The average aspect ratio is an average value of aspect ratios of the spherical particles and is obtainable in a similar manner to the method described in the examples. The aspect ratio is synonymous with “Aspect Ratio” defined by ISO 9276-6.

In contrast, the granular resin composition described in Patent Literature 1 is obtained by being cut by a plurality of knives of the pulverization-type granulator during its production. Therefore, the shapes of particles included in the granular resin composition are uncontrollable, and the shape of each particle included in the granular resin composition is not spherical.

Moreover, saying that the resin composition includes aggregates of the spherical particles includes not only a case where the resin powder consists of the spherical particles of the resin composition but also a case where the resin powder includes non-spherical particles of the resin composition within a range not impairing the effect of the present disclosure.

The resin powder has the above-described configuration, and therefore, when the resin powder is handled, friction of the spherical particles is less likely to be caused, so that fine particles are less likely to be produced. Therefore, when the resin powder is used as a semiconductor sealing material in a compression molding method, contamination of facilities, troubles in measurement, and the like due to scattering of fine particles are less likely to be caused. Moreover, the resin powder is not aggregates of conventional fragment particles but is aggregates of spherical particles and is thus not bulky. Therefore, when the resin powder is used as the semiconductor sealing material in the compression molding method, the resin powder is easily uniformly put in a cavity formed in a mold, and thus, it is possible to reduce the occurrence of poor appearance of a sealing resin obtained by melting and then curing the resin powder as compared to a case where the aggregates of the conventional fragment particles are used.

In volume particle size distribution of the resin powder, the upper limit of a mean particle size (hereinafter referred to as a volume mean particle size) is preferably 200 μm, more preferably 100 μm. The lower limit of the volume mean particle size of the resin powder is preferably 1 μm, more preferably 10 μm. When the volume mean particle size of the resin powder is within the above-described range, for example, the resin powder may suitably be used as the semiconductor sealing material. The volume mean particle size of the resin powder is obtainable in a similar manner to the method described in the examples.

In the volume particle size distribution, the upper limit of the ratio of spherical particles of the resin composition having a particle size (hereinafter referred to as a volume particle size) larger than or equal to 50 μm and smaller than or equal to 100 μm is preferably 100 wt. % with respect to the entirety of the spherical particles of the resin composition. The lower limit of the ratio of spherical particles of the resin composition having a volume particle size of larger than or equal to 50 μm and smaller than or equal to 100 μm is more preferably 70 wt. %, much more preferably 80 wt. %, particularly preferably 90 wt. % with respect to the entirety of the spherical particles of the resin composition. When the ratio of the spherical particles of the resin composition having a volume particle size larger than or equal to 50 μm and smaller than or equal to 100 μm is within the above-described range, the volume particle size distribution of the resin powder can be evaluated as being sharp, and when the resin powder is used as the semiconductor sealing material in the compression molding method, the resin powder is more easily put in a target location in the cavity formed in the mold.

In contrast, the granular resin composition described in Patent Literature 1 is obtained by being cut by a plurality of knives of the pulverization-type granulator during its production. Therefore, the size of the granular resin composition is uncontrollable, and the volume particle size distribution of the granular resin composition can be evaluated as being broad.

The ratio of the spherical particles of the resin composition having a particle size larger than or equal to 50 μm and smaller than or equal to 100 μm is obtainable in a similar manner to the method described in the examples. Examples of a method for adjusting the ratio of spherical particles of the resin composition having a volume particle size of larger than or equal to 50 μm and smaller than or equal to 100 μm to be within the above-described range include a method for granulating slurry by a spray-dry method as described later and a method for classifying resin powder by sieving the resin powder.

The resin powder preferably has one frequency peak in the volume particle size distribution. Thus, the resin powder is more easily put in a target location in the cavity formed in the mold. Moreover, when the resin powder is exposed to a temperature at which the resin powder melts, the resin powder is easily uniformly melted, so that a sealing material thus obtained is less likely to have poor appearance. The existence of the frequency peak can be confirmed in a similar manner to the method described in the examples.

Examples of a method by which the resin powder is adjusted to have one frequency peak include a method for granulating slurry by a spray-dry method as described later and a method for classifying resin powder by sieving the resin powder.

In number particle size distribution, the resin powder preferably has at least one frequency peak in each of a range in which the particle size is larger than or equal to 1 μm and smaller than or equal to 10 μm and a range in which the particle size is larger than 10 μm and smaller than or equal to 100 μm. Thus, spherical particles having a small particle size enter gaps each formed between the spherical particles having a large particle size, thereby reducing the bulkiness of the resin powder, and it becomes easy to more uniformly put the resin powder in the cavity formed in the mold. The existence of the frequency peak can be confirmed in a similar manner to the method described in the examples.

Examples of a method by which the resin powder is adjusted to have at least one frequency peak in each of the range in which the particle size is larger than or equal to 1 μm and smaller than or equal to 10 μm and the range in which the particle size is larger than 10 μm and smaller than or equal to 100 μm in the number particle size distribution include a method for granulating slurry by a spray-dry method as described later and a method for classifying resin powder by sieving the resin powder.

The upper limit of the average circularity of the resin powder is preferably 1.00. The lower limit of the average circularity of the resin powder is preferably 0.90, more preferably 0.95, much more preferably 0.98. When the average circularity of the resin powder is within the above-described range, the resin powder is more easily put uniformly in the cavity formed in the mold when the resin powder is used as the semiconductor sealing material in the compression molding method.

Examples of a method for adjusting the average circularity of the resin powder to be within the above-described range include a method in which when slurry is granulated as described later by a spray-dry method, a rotary atomizer method is adopted, and the rotation speed of a disk of a rotary atomizer is adjusted.

The upper limit of the average aspect ratio of the resin powder is preferably 1.00. The lower limit of the average aspect ratio of the resin powder is preferably 0.80, more preferably 0.85, much more preferably 0.90. When the average aspect ratio of the resin powder is within the above-described range, the resin powder is more easily put uniformly in the cavity formed in the mold when the resin powder is used as the semiconductor sealing material in the compression molding method.

Examples of a method for adjusting the average aspect ratio of the resin powder to be within the above-described range include a method in which when slurry is granulated as described later by a spray-dry method, a rotary atomizer method is adopted, and the rotation speed of a disk of a rotary atomizer is adjusted.

Each spherical particle preferably includes: a core including at least one or more electrically insulative inorganic particle; and a resin component covering the entirety of the core. This reduces fine particles produced due to friction of the spherical particles when the resin powder is handled as compared to a case of including spherical particles with surfaces at which electrically insulative inorganic particles are uncovered. Moreover, when the resin powder is thermally melted during molding, the resin components of adjacent spherical particles form a skin layer, thereby improving wettability and resulting in spherical particles which easily flow.

Whether or not each spherical particle includes a core and a resin component that covers the entirety of the core can be confirmed in a similar manner to the method described in the examples. Each spherical particle can be adjusted to include a core and a resin component covering the entirety of the core by, for example, changing the viscosity of slurry as described later. Examples of a method for adjusting each spherical particle to include a core and a resin component covering the entirety of the core include a granulation method by a spray-dry method.

The resin component is preferably in an uncured state. That is, the resin component is preferably evaluated as being in a state corresponding to A-stage. Thus, when the resin powder is used as the semiconductor sealing material in the compression molding method, it is possible to reduce the occurrence of poor appearance of a sealant obtained.

In contrast, when the granular resin composition described in Patent Literature 1 is produced, the granular resin composition is melt-kneaded with a twin-shaft kneader at 100° C. for a predetermined time. Thus, the resin component in the granular resin composition can be evaluated as being in a state corresponding to B stage and may contain a grain in a state corresponding to C-stage (hereinafter referred to as a cured grain) which is a state after reaction proceeds during the melt-kneading. The cured grain does not melt even when the granular resin composition is exposed to a temperature at which the granular resin composition melts, and therefore, the sealing material obtained may have poor appearance.

Here, A-stage, B-stage, and C-stage are respectively synonymous with A-stage, B-stage, and C-stage defined in Japanese Industrial Standards (JIS) K6900:1994. That is, A-stage refers to an initial stage during preparation of a certain kind of thermosetting resin. In the initial stage, a material for the thermosetting resin is still soluble and fusible in a certain kind of liquid. B-stage refers to an intermediate stage during a reaction of the certain kind of thermosetting resin. In the intermediate stage, the material swells when coming into contact with the certain kind of liquid and the material softens when heated, but the material does not fully dissolve or melt. C-stage refers to a final stage during the reaction of the certain kind of thermosetting resin. In the final stage, the material for the thermosetting resin is virtually insoluble and infusible. The resin component may be brought into an uncured state by, for example, changing the viscosity of slurry as described later. Examples of a method for bringing the resin component into an uncured state include a granulation method by a spray-dry method.

The upper limit of a metal content of the resin powder is preferably 1 ppm, more preferably 0.5 ppm with respect to the resin powder. When the upper limit of the metal content of the resin powder is within the above-described range, corrosion and the like of a wire is suppressed, and the reliability of the sealing material obtained is improved when the resin powder is used as the semiconductor sealing material in the compression molding method. In contrast, the granular resin composition described in Patent Literature 1 is obtained by melt-kneading with a twin-shaft kneader and cutting with a plurality of knives of the pulverization-type granulator during production of the granular resin composition. Thus, the granular resin composition may contain a metal component derived from a facility during a manufacturing process of the granular resin composition. The metal content of the resin powder is obtainable in a similar manner to the method described in the examples. Examples of a method for adjusting the metal content of the resin powder to be within the above-described range include granulating slurry by a spray-dry method as described later.

The upper limit of an acetone insoluble amount of the resin powder is preferably 1 ppm, more preferably 0.5 ppm with respect to the resin powder. When an acetone insoluble component of the resin powder is within the above-described range, the resin powder contains almost no component similar to cured material. When the resin powder is used as the semiconductor sealing material in the compression molding method, a filling defect is less likely to occur when the resin powder is melted and molded, and it is possible to reduce the occurrence of poor appearance of the sealing material obtained. The acetone insoluble component is obtainable in a similar manner to the method described in the examples. Examples of a method for adjusting the acetone insoluble component to be within the above-described range include granulating slurry by a spray-dry method as described later.

The upper limit of a remaining solvent amount of the resin powder is preferably 1 wt. %, more preferably 0.5 wt. % with respect to the resin powder. When the remaining solvent amount of the resin powder is within the above-described range, the occurrence and the like of a void in the sealing material obtained is suppressed, and the reliability of the sealing material obtained is improved when the resin powder is used as the semiconductor sealing material in the compression molding method. The remaining solvent amount of the resin powder is obtainable in a similar manner to the method described in the examples. Examples of a method for adjusting the remaining solvent amount of the resin powder to be within the above-described range include granulating slurry by a spray-dry method as described later.

(1.1) Resin Composition

The resin composition contains a non-resin component and a resin component.

(1.1.1) Non-Resin Component

The non-resin component includes electrically insulative inorganic particles. The electrically insulative inorganic particles are electrically insulating. “Electrical insulating” means that the volume specific resistivity of a material for the electrically insulative inorganic particles is greater than or equal to 1×10⁹ Ω/cm. Examples of a material for such electrically insulative inorganic particles include metal oxides, metal nitrides, metal carbonates, and metal hydroxides. Examples of the metal oxides include alumina, melted silica, crystallinity silica, magnesium oxide, calcium oxide, titanium oxide, beryllium oxide, copper oxide, cuprous oxide, and zinc oxide. Examples of the metal nitrides include boron nitride, aluminum nitride, and silicon nitride. Examples of metal carbonates include magnesium carbonate and calcium carbonate. Examples of metal hydroxides include aluminum hydroxide and magnesium hydroxide. The electrically insulative inorganic particles in the resin powder may include one kind of material or may include two or more kinds of materials.

The shape of the electrically insulative inorganic particles may accordingly be selected in accordance with applications and the like of the resin powder. Examples of the shape include spherical, flat, elliptic, tubular, wire-like, needle-like, plate-like, peanut-like, and indefinite shapes. A melted substance of a resin composition obtained by melting resin powder is preferably spherical for its excellent fluidity and the like. The electrically insulative inorganic particles in the resin powder may include one kind of shape or may include two or more kinds of shapes.

The size of the electrically insulative inorganic particles in the resin powder is at least smaller than the size of the spherical particles of the resin powder. The content of the electrically insulative inorganic particles in the spherical particles of the resin composition is not particularly limited. The upper limit of the content of the electrically insulative inorganic particles is preferably 90 volume %, more preferably 85 volume % with respect to the spherical particles of the resin composition. The lower limit of the content of the electrically insulative inorganic particles is preferably 40 volume %, more preferably 50 volume % with respect to the spherical particles of the resin composition.

(1.1.2) Resin Component

The resin component includes a thermosetting resin. The thermosetting resin is a reactive compound which may cause crosslinking reaction due to heat. Examples of the thermosetting resin include epoxy resins, imide resins, phenol resins, cyanate resins, melamine resins, and acrylic resins. Examples of the epoxy resins include a bisphenol A epoxy resin, a bisphenol F epoxy resin, a polyfunctional epoxy resin, a biphenyl epoxy resin, a cresol novolac epoxy resin, and a phenol novolac epoxy resin. The polyfunctional epoxy resin is a resin having three or more epoxy groups per molecule. Examples of the imide resins include a bisallylnadimide resin. The resin component may include one kind of thermosetting resin or may include two or more kinds of thermosetting resins. The content of the resin component is not particularly limited. The upper limit of the resin component is preferably 60 volume %, more preferably 50 volume % with respect to the spherical particles of the resin composition. The lower limit of the resin component is preferably 10 volume %, more preferably 15 volume % with respect to the spherical particles of the resin composition.

The resin component may further contain a curing agent in accordance with the kind and the like of the thermosetting resin. The curing agent is an additive that cures the thermosetting resin. Examples of the curing agent include dicyandiamide, a phenol-based curing agent, cyclopentadiene, an amine-based curing agent, and acid anhydride. The phenol-based curing agent has two or more phenolic hydroxyl groups per molecule. Examples of the phenol-based curing agent include a phenol novolac resin, a phenol aralkyl resin, a naphthalene-type phenol resin, and a bisphenol resin. Examples of the bisphenol resin include a bisphenol A resin and a bisphenol F resin.

The resin component may further contain a curing accelerator in accordance with the kind and the like of the thermosetting resin. Examples of the curing accelerator include tertiary amine, tertiary amine salt, imidazole, phosphine, and phosphonium salt. As the imidazole, 2-ethyl-4-methylimidazole and the like may be used.

The resin component may further contain a coupling agent in accordance with the kind and the like of the thermosetting resin. Thus, when slurry is granulated by the spray-dry method as described later, homogeneity of the resin component with the electrically insulative inorganic particles is improved to obtain more uniform slurry. Examples of the silane coupling agent includes epoxy silane, amino silane, titanate aluminum chelate, and zircoaluminate.

The resin component may further contain a dispersant in accordance with the kind and the like of the thermosetting resin. Thus, when slurry is granulated by the spray-dry method as described later, the viscosity of the slurry is reduced and homogeneity of the resin component with the electrically insulative inorganic particles is improved to obtain more uniform slurry. Examples of the dispersant include higher fatty acid ester phosphate, an amine base of higher fatty acid ester phosphate, and an alkylene oxide of higher fatty acid ester phosphate. Examples of the higher fatty acid ester phosphate include octyl ester phosphate, decyl ester phosphate, and lauryl ester phosphate.

The resin component may further contain a thermoplastic resin, an elastomer, flame retardant, a coloring agent, a thixotropy imparting agent, an ion trapping agent, a coloring agent, a thixotropy imparting agent, a surfactant, a levelling agent, defoamant, and reactive diluent in accordance with applications and the like of the resin powder. Examples of the thermoplastic resin include a phenoxy resin. Examples of the elastomer include a thermosetting elastomer and a thermoplastic elastomer. Examples of the flame retardant include a brominated epoxy resin and antimony oxide.

(1.2) Applications of Resin Powder

The resin powder is preferably used as a raw material for a semiconductor sealing material and an insulating material of a printed circuit board. When the resin powder is used in the semiconductor sealing material, a resin seal technique of a semiconductor element is not particularly limited. Examples of the resin seal technique include a transfer molding method, a compression molding method, and an underfill technique. Among them, the compression molding method is preferably used, for example, because fine particles are less likely produced while the resin powder is handled and the resin powder is easily uniformly put in the cavity formed in the mold. Moreover, the melted substance of the resin composition obtained by melting the resin powder is preferably used in the underfill technique and/or an insulating material for a printed circuit board, for example, because the melted substance has excellent fluidity, packing efficiency, and embedding properties of a circuit of printed wiring.

(2) Semiconductor Sealing Material

The semiconductor sealing material (hereinafter referred to as a semiconductor sealing material) of the present embodiment includes the above-described resin powder. The form of the semiconductor sealing material may accordingly be selected in accordance with the applications and the like of the semiconductor sealing material and may be, for example, a solid, liquid, paste, or film form. Examples of the solid form include a powder form and a tablet form. The paste form means that the semiconductor sealing material has fluidity at a room temperature even when the semiconductor sealing material contains no solvent. In accordance with the use form and the like of the semiconductor sealing material, materials for the semiconductor sealing material may only the resin powder or may contain a solvent, an ultraviolet curable resin, a thermosetting resin, a thermoplastic resin, or the like in addition to the resin powder. These resins except for the resin powder may be in a liquid form or a solid form such as powder at an ordinary temperature.

(3) Resin Powder Manufacturing Method

A resin powder manufacturing method according to the present embodiment includes preparing slurry, and granulating the slurry by a spray-dry method. Slurry contains a resin component and electrically insulative inorganic particles. Thus, the above-described resin powder is obtained. Moreover, the spray-dry method enables the resin powder to be produced from a constituent component of a resin component which is not melt-kneaded even with kneading performed with a conventional kneader at 100° C. and which cannot be molded into powder or a sheet shape.

(3.1) Preparation of Slurry

Examples of a method for preparing the slurry include a method in which powder (hereinafter referred to as inorganic powder) including the above-described electrically insulative inorganic particles, the above-described resin component, and optionally a solvent are added and agitated to be uniformly mixed.

The mean particle size of the inorganic powder is accordingly selected in accordance with the applications and the like of the resin powder. The upper limit of the mean particle size of the inorganic powder is preferably 75 μm, more preferably 50 μm. The lower limit of the mean particle size of the inorganic powder is preferably 1 μm, more preferably 5 μm. The mean particle size of the inorganic powder refers to a particle size at an integrated value of 50% in particle size distribution measured based on a particle size distribution measurement device based on a laser scattering/diffraction method.

The addition ratio of the inorganic powder is accordingly selected in accordance with the applications and the like of the resin powder. The upper limit of the blending ratio of the inorganic powder is preferably 95 parts by mass, more preferably 85 parts by mass with respect to 100 parts by mass of a solid content of the slurry. The lower limit of the addition ratio of the inorganic powder is preferably 40 parts by mass, more preferably 50 parts by mass with respect to 100 parts by mass of the solid content of the slurry. When the blending ratio of the inorganic powder is within the above-described range, the resin powder may suitably be used as the semiconductor sealing material. The solid content in the slurry is the content of the electrically insulative inorganic particles and the resin component except for a solvent.

The constituent component such as the thermosetting resin and the like constituting the resin component may be in liquid form or solid form such as powder at an ordinary temperature as long as it can be prepared as slurry. That is, the constituent component of the resin component is not particularly limited and may be a resin, like a conventional one, which cannot be melt-kneaded when subjected to kneading with a kneader at 100° C. as long as the resin can be prepared as slurry.

Examples of the constituent component that cannot be melt-kneaded when the constituent component is subjected to kneading at 100° C. include a resin and the like whose melting point is higher than or equal to 140° C. Examples of the resin whose melting point is higher than or equal to 140° C. include an imide resin, 4,4′-bismaleimide diphenyl methane, and the like from which cured material having excellent heat resistance is obtained.

The upper limit of the content of the thermosetting resin is preferably 65 parts by mass, more preferably 55 parts by mass with respect to 100 parts by mass of a solid content of the slurry. The upper limit of the content of thermosetting resin is preferably 10 parts by mass, more preferably 15 parts by mass with respect to 100 parts by mass of a solid content of the slurry.

The upper limit of the content of the curing agent is preferably 50 parts by mass with respect to the solid content of the slurry. The content of the curing accelerator is accordingly adjusted in accordance with the kind of the thermosetting resin and the curing agent. The upper limit of the content of the coupling agent is preferably 1 part by mass with respect to 100 parts by mass of a solid content of the slurry.

As a solvent, methyl ethyl ketone (MEK), N,N-dimethylformamide (DMF), acetone, methyl isobutyl ketone (MIBK), or the like may be used. Only one kind of solvent may be used, or two or more kinds of solvents may be used in combination. When two or more kinds of solvents are combined with each other, the mixing ratio (mass ratio and volume ratio) is not particularly limited. The content of the solvent is not particularly limited. The upper limit of the content ratio of the solid content in the slurry is preferably 99 wt. %, more preferably 98 wt. % with respect to the slurry. The lower limit of the content ratio of the solid content in the slurry is preferably 50 wt. %, more preferably 60 wt. % with respect to the slurry.

(3.2) Granulation by Spray-Dry Method

Examples of a method for granulating slurry by a spray-dry method include a method of collecting powder obtained by putting slurry in a spray dryer. The spray dryer atomizes the slurry by spraying the slurry in the dryer and continuously brings the slurry into contact with hot air while a surface area per unit volume is increased, thereby performing instantaneous drying and granulation. That is, the slurry is formed into droplets each having a certain size, the droplets are rapidly dried, and the droplets are formed into a spherical shape by surface tension, thereby obtaining spherical powder having substantially the same particle size. Thus, powder which is very fine and which is easily scattered is less likely to be produced. In contrast, when the viscosity of the slurry is appropriate, the slurry can be formed into droplets which are not too large. Therefore, resin powder having substantially uniform particle size is obtained, and thus, problems in connection with the pulverized powder are less likely to be caused. As described above, when the spray dryer is used, resin powder including spherical particles with a sharp frequency in the volume particle size distribution is obtained, and therefore, unlike conventional cases, sieving the granular resin composition for classification is no longer required. Thus, for example, resin powder collected from the spray dryer can be used as is as the semiconductor sealing material, and a classification step performed when the semiconductor sealing material is produced may be omitted, which significantly reduces time as compared to conventional cases. Moreover, unlike conventional cases, melt-kneading of the inorganic powder and the resin component with a kneader to obtain a product and cutting of the product with a pulverization-type granulator are no longer required, and thus, resin powder obtained includes no metal foreign substance. Moreover, the resin component of the resin powder obtained comes into contact with hot air only instantaneously, and therefore, the resin component has almost no heat history and can be evaluated as being in a state corresponding to A-stage.

A spray method of the slurry is not particularly limited, and examples of the spray method include a rotary atomizer method and a nozzle method. In the rotary atomizer method, a solution of the slurry is continuously sent to a disk rotating at a high speed and is sprayed by using centrifugal force. When the rotary atomizer method is used, resin powder having a particle size of larger than or equal to 20 μm and smaller than or equal to 200 μm and having a sharp frequency in the volume particle size distribution is easily obtained. The upper limit of the rotation speed of the disk is preferably 25000 rpm, more preferably 20000 rpm. The lower limit of the rotation speed of the disk is preferably 5000 rpm, more preferably 10000 rpm. As the rotation speed of the disk is increased, the volume mean particle size of the resin powder obtained is reduced. As the rotation speed of the disk is reduced, the volume mean particle size of the resin powder obtained is increased, and thus, particles which are true circle are obtained. That is, as the rotation speed of the disk is reduced, resin powder whose average circularity and average aspect ratio are each close to 1.0 is easily obtained. Examples of the nozzle method include a two-fluid nozzle method and a one-fluid nozzle method. When the two-fluid nozzle method is used, resin powder whose particle size is smaller than or equal to 20 μm in the volume particle size distribution is easily obtained, and adjusting a slurry feed rate enables the volume mean particle size of the resin powder obtained to be adjusted. The upper limit of the slurry feed rate is preferably 2.0 kg/hour. The lower limit of the slurry feed rate is preferably 0.5 kg/hour. Increasing the slurry feed rate increases the volume mean particle size of the resin powder obtained.

A thermal drying condition of the spray dryer is not particularly limited, and, for example, drying is performed at a normal pressure. The upper limit of the temperature (entrance temperature) of hot air to be supplied is preferably 200° C., more preferably 150° C. The lower limit of the entrance temperature is preferably 60° C., more preferably 80° C. The upper limit of a temperature (outlet temperature) at an outlet of the dryer is preferably 170° C., more preferably 120° C. The lower limit of the outlet temperature is preferably 30° C., more preferably 50° C.

A collection method of the resin powder is not particularly limited and may be accordingly selected in accordance with the applications and the like of the resin powder. Examples of the collection method include a two-point collection method, a cyclone collection method, and a bagfilter collection method. The two-point collection method performs collection at two points, namely, under a drying chamber and under a cyclone connected to the dryer and has a classification effect. Under the dryer, spherical resin powder is obtained, and under the cyclone, resin powder including fine particles is obtained. The cyclone collection method performs collection collectively by the cyclone connected to the drying chamber. The bagfilter collection method performs collection collectively by a bagfilter connected to the drying chamber and is suitable for collection of fine particles which cannot be obtained by the cyclone collection method.

### Second Embodiment

(1) Resin Powder

Resin powder of the present embodiment (hereinafter referred to as resin powder) includes aggregates of spherical particles of a resin composition. The resin composition contains a resin component and a non-resin component (in the present embodiment, magnetic particles). Detailed description of components similar to those in the first embodiment is omitted below.

The resin powder has the above-described configuration and is thus easily handled. That is, when the resin powder is handled, friction of the spherical particles is less likely to be caused, and generation of fine particles is further suppressed. Thus, contamination of facilities, troubles in measurement, and the like due to scattering of fine particles are less likely to be caused. Moreover, the resin powder is not aggregates of conventional fragment particles but is aggregates of spherical particles and is thus not bulky. Thus, the resin powder has excellent packing efficiency.

In volume particle size distribution of the resin powder, the upper limit of a mean particle size (hereinafter referred to as a volume mean particle size) is preferably 200 μm, more preferably 100 μm. The lower limit of the volume mean particle size of the resin powder is preferably 1 μm, more preferably 10 μm. When the volume mean particle size of the resin powder is within the above-described range, a property that the eddy current in the magnetic particles can be reduced and moldability are balanced. That is, resin powder is easily filled with high density, and the viscosity of the resin powder thermally melted is also less likely to be increased as compared to resin powder having volume average particle out of the above-described range. Therefore, the moldability is less likely to be degraded, and when the resin powder is used as the raw material for a powder magnetic core, the eddy current loss of the powder magnetic core can be suppressed. The volume mean particle size of the resin powder is obtainable in a similar manner to the method described in the examples.

In the volume particle size distribution, the upper limit of the ratio of spherical particles of the resin composition having a particle size (hereinafter referred to as a volume particle size) larger than or equal to 50 μm and smaller than or equal to 100 μm is preferably 100 wt. % with respect to the entirety of the spherical particles of the resin composition. The lower limit of the ratio of spherical particles of the resin composition having a volume particle size of larger than or equal to 50 μm and smaller than or equal to 100 μm is preferably 70 wt. %, much more preferably 80 wt. % with respect to the entirety of the spherical particles of the resin composition. When the ratio of the spherical particles of the resin composition having a volume particle size larger than or equal to 50 μm and smaller than or equal to 100 μm is within the above-described range, the volume particle size distribution of the resin powder can be evaluated as being sharp, and the resin powder is much less likely to be scattered.

The resin powder preferably has one frequency peak in the volume particle size distribution. Thus, the resin powder is much less likely to be scattered.

In number particle size distribution, the resin powder preferably has at least one frequency peak in each of a range in which the particle size is larger than or equal to 1 μm and smaller than or equal to 10 μm and a range in which the particle size is larger than 10 μm and smaller than or equal to 100 μm. Thus, spherical particles having a small particle size enter gaps each formed between the spherical particles having a large particle size, the bulkiness of the resin powder is further reduced, and the resin powder has more excellent packing efficiency.

The upper limit of the average circularity of the resin powder is preferably 1.00. The lower limit of the average circularity of the resin powder is preferably 0.90, more preferably 0.95, much more preferably 0.98. When the average circularity of the resin powder is within the above-described range, friction of the spherical particles is less likely to be caused when the resin powder is handled, and the fine particles are further suppressed from being produced, and the resin powder is more easily handled.

The average circularity of the resin powder can be adjusted to be within the above-described range by, for example, changing the viscosity of slurry as described later. Examples of a method for adjusting the average circularity of the resin powder to be within the above-described range include a method in which granulation is performed by a spray-dry method, a rotary atomizer method is adopted, and the rotation speed of a disk of a rotary atomizer is adjusted.

The upper limit of the average aspect ratio of the resin powder is preferably 1.00. The lower limit of the average aspect ratio of the resin powder is preferably 0.80, more preferably 0.85, much more preferably 0.90. When the average aspect ratio of the resin powder is within the above-described range, friction of the spherical particles is less likely to be caused when the resin powder is handled, and the fine particles are further suppressed from being produced, and the resin powder is more easily handled.

The average aspect ratio of the resin powder can be adjusted to be within the above-described range by, for example, changing the viscosity of slurry as described later. Examples of a method for adjusting the average aspect ratio of the resin powder to be within the above-described range include a method in which when granulation is performed by a spray-dry method, a rotary atomizer method is adopted, and the rotation speed of a disk of a rotary atomizer is adjusted.

Each spherical particle preferably includes a core including at least one or more magnetic particles and a resin component covering the entirety of the core. This reduces friction of the spherical particles is less likely to be caused and generation of fine particles is further suppressed when the resin powder is handled as compared to a case of including spherical particles with surfaces at which magnetic particles are in an uncovered state. Moreover, when the resin powder is thermally melted during molding, the resin components of adjacent spherical particles form a skin layer, thereby improving wettability and resulting in spherical particles which easily flow.

Whether or not each spherical particle includes a core and a resin component that covers the entirety of the core can be confirmed in a similar manner to the method described in the examples. Each spherical particle can be adjusted to include a core and a resin component covering the entirety of the core by, for example, changing the viscosity of slurry as described later. Examples of a method for adjusting each spherical particle to include a core and a resin component covering the entirety of the core include a granulation method by a spray-dry method.

The resin component is preferably in an uncured state. That is, the resin component is preferably evaluated as being in a state corresponding to A stage. Thus, the resin component thus obtained does not include a grain in a state corresponding to C-stage (hereinafter referred to as a cured grain), and therefore, for example, it is possible to reduce the occurrence of poor appearance of cured material obtained by heat melting and curing resin powder. The cured grain does not melt even when exposed to heat, and therefore, cured material obtained may have poor appearance.

The upper limit of an acetone insoluble amount of the resin powder is preferably 2 ppm, more preferably 1 ppm with respect to the resin powder. When an acetone insoluble component of the resin powder is within the above-described range, the resin powder contains almost no component similar to cured material, and a filling defect is less likely to occur when the resin powder is melted and molded, and it is possible to reduce the occurrence of poor appearance of the cured material obtained. The acetone insoluble component is obtainable in a similar manner to the method described in the examples. Examples of a method for adjusting the acetone insoluble component to be within the above-described range include granulating slurry by a spray-dry method as described later.

The upper limit of a remaining solvent amount of the resin powder is preferably 1 wt. %, more preferably 0.5 wt. % with respect to the resin powder. When the remaining solvent amount of the resin powder is within the above-described range, a void is suppressed from being formed in a cured material obtained by heat melting and then curing the resin powder. The remaining solvent amount of the resin powder is obtainable in a similar manner to the method described in the examples. Examples of a method for adjusting the remaining solvent amount of the resin powder to be within the above-described range include granulating slurry by a spray-dry method as described later.

(1.1) Resin Composition

The resin composition contains a non-resin component and a resin component.

(1.1.1) Non-Resin Component

The non-resin component includes magnetic particles. The magnetic particles are particles including a substance (magnetic body) which can be magnetized by an external magnetic field.

Examples of materials for the magnetic particles include a hard-magnetic material and a soft magnetic material. Examples of the hard-magnetic material include NdFeB, NdFe bond magnet, and LaCoSr ferrite (LaₓSr₁₋ₓFe₁₂O₁₉). Examples of the soft magnetic material include a metal-based soft magnetic material, spinel-based ferrite, garnet-based ferrite, hexagonal crystal ferrite, iron oxide, chromium oxide, and cobalt. The metal-based soft magnetic material is a non-oxide material containing iron as a main component. Examples of the metal-based soft magnetic material include carbonyl iron, an electromagnetic steel plate, Permalloy, an amorphous alloy, and a nanocrystalline metal magnetism material. Examples of the amorphous alloy include a Fe-based amorphous alloy and a Co-based amorphous alloy. The nanocrystalline metal magnetism material is a material obtained by nanocrystallization of the Fe-based amorphous alloy by a heat process. The spinel-based ferrite includes a composition of MFe₂O₃. M is bivalent metal, and may include Mn, Zn, and Fe (MnZn ferrite) or may include mainly Ni, Zn, and Cu (NiZn ferrite). Examples of a garnet-based ferrite include GdₓY₃₋ₓFe₅O₁₂ (Gd-substituted YIG). Examples of a hexagonal crystal-based ferrite include a magnetoplumbite (M)-type ferrite and a Ferroxplana-type ferrite. The M-type ferrite has a Ba ferrite or Sr ferrite as an initial composition, part of which is substituted by Ti, Ca, Cu, Co, or the like. Examples of Ferroxplana include W type (Ba₁M₂Fe₁₆O₂₇), Y type (Ba₂M₂Fe₁₂O₂₂), and Z type (Ba₃M₂Fe₂₄O₄₁). In the formula, M is a divalent metal. The magnetic particles in the resin powder may include one kind of material or may include two or more kinds of materials.

The shape of the magnetic particles may accordingly be selected in accordance with applications and the like of the resin powder. Examples of the shape include spherical, flat, elliptic, tubular, wire-like, needle-like, plate-like, peanut-like, and indefinite shapes. The magnetic particles in the resin powder may include one kind of shape or may include two or more kinds of shapes.

The magnetic particles may be subjected to an insulation process in accordance with the application and the like of the resin powder. That is, each magnetic particle may have a surface covered with an electrically insulating coating. This suppresses inter-particle eddy current flowing between adjacent magnetic particles from being generated and enables an eddy current loss to be further reduced. Examples of a method of the insulation process include a method in which magnetic powder and an aqueous solution containing electrically insulating fillers are mixed with each other and dried. Examples of materials for the electrically insulating fillers include phosphoric acid, boric acid, and magnesium oxide.

The size of magnetic particles in the resin powder is at least smaller than the size of the spherical particles of the resin powder. The content of the magnetic particles in the spherical particles of the resin composition is not particularly limited. The upper limit of the content of the electrically insulative inorganic particles is preferably 90 volume %, more preferably 85 volume % with respect to the spherical particles of the resin composition. The lower limit of the content of the electrically insulative inorganic particles is preferably 40 volume %, more preferably 50 volume % with respect to the spherical particles of the resin composition.

(1.1.2) Resin Component

The resin component may further contain a coupling agent in accordance with the kind and the like of the thermosetting resin. Thus, when slurry is granulated by the spray-dry method as described later, homogeneity of the resin component with the magnetic particles is improved to obtain more uniform slurry. Examples of the silane coupling agent includes epoxy silane, amino silane, titanate aluminum chelate, and zircoaluminate.

The resin component may further contain a dispersant in accordance with the kind and the like of the thermosetting resin. Thus, when slurry is granulated by the spray-dry method as described later, the viscosity of the slurry is reduced and homogeneity of the resin component with the magnetic particles is improved to obtain more uniform slurry. Examples of the dispersant include higher fatty acid ester phosphate, an amine base of higher fatty acid ester phosphate, and an alkylene oxide of higher fatty acid ester phosphate. Examples of the higher fatty acid ester phosphate include octyl ester phosphate, decyl ester phosphate, and lauryl ester phosphate.

(1.2) Applications of Resin Powder

The resin powder is suitably used as a raw material of, for example, a line filter, a radio wave absorber, a transformer, a magnetic shielding, an inductor (coil), a temperature switch, an actuator, a static magnetic wave element, toner of a copier, marker of an explosive, a semiconductor sealing material, and an insulating material of a printed circuit board.

(2) Resin Powder Manufacturing Method

A resin powder manufacturing method according to the present embodiment includes preparing slurry, and granulating the slurry by a spray-dry method. The slurry contains a resin component and magnetic particles. As described above, since magnetic powder which is a raw material of magnetic particles are mixed in the slurry, the resin powder is free from risk of being scattered when the resin powder is produced. Moreover, the spray-dry method enables the resin powder to be produced from a constituent component of a resin component which is not melt-kneaded even with kneading performed with a conventional kneader at 100° C. and which cannot be molded into powder or a sheet shape.

(2.1) Preparation of Slurry

Examples of a method for preparing the slurry include a method in which powder (hereinafter referred to as magnetic powder) including the above-described magnetic particles, the above-described resin component, and optionally a solvent are added and agitated to be uniformly mixed.

The mean particle size of the magnetic powder is accordingly selected in accordance with the applications and the like of the resin powder. The upper limit of the mean particle size of the magnetic powder is preferably 75 μm, more preferably 50 μm. The lower limit of the mean particle size of the magnetic powder is preferably 1 μm, more preferably 5 μm. The mean particle size of the magnetic powder refers to a particle size at an integrated value of 50% in particle size distribution measured based on a particle size distribution measurement device based on a laser scattering/diffraction method.

The addition ratio of the magnetic powder is accordingly selected in accordance with the applications and the like of the resin powder. The upper limit of the blending ratio of the magnetic powder is preferably 95 parts by mass, more preferably 85 parts by mass with respect to 100 parts by mass of a solid content of the slurry. The lower limit of the addition ratio of the magnetic powder is preferably 40 parts by mass, more preferably 50 parts by mass with respect to 100 parts by mass of the solid content of the slurry. When the blending ratio of the magnetic powder is within the above-described range, the resin powder may be preferably used as the magnetic material. The solid content in the slurry is a content of the magnetic particles and the resin component except for a solvent.

The upper limit of the content of the thermosetting resin is preferably 65 parts by mass, more preferably 55 parts by mass with respect to 100 parts by mass of a solid content of the slurry. The lower limit of the content of thermosetting resin is preferably 2 parts by mass, more preferably 5 parts by mass with respect to 100 parts by mass of a solid content of the slurry.

(2.2) Granulation by Spray-Dry Method

Examples of a method for granulating slurry by a spray-dry method include a method of collecting powder obtained by putting slurry in a spray dryer. The spray dryer atomizes the slurry by spraying the slurry in the dryer and continuously brings the slurry into contact with hot air while a surface area per unit volume is increased, thereby performing instantaneous drying and granulation. That is, the slurry is formed into droplets each having a certain size, the droplets are rapidly dried, and the droplets are formed into a spherical shape by surface tension, thereby obtaining spherical powder having substantially the same particle size. Thus, powder which is very fine and which is easily scattered is less likely to be produced. In contrast, when the viscosity of the slurry is appropriate, the slurry can be formed into droplets which are not too large. Therefore, resin powder having substantially uniform particle size is obtained, and thus, problems in connection with the pulverized powder are less likely to be caused. As described above, when the spray dryer is used, resin powder including spherical particles with a sharp frequency in the volume particle size distribution is obtained, and therefore, sieving for classification is no longer required. Moreover, melt-kneading of the magnetic powder and the resin component with a kneader to obtain a product and cutting of the product with a pulverization-type granulator are no longer required, and thus, resin powder obtained includes no metal foreign substance. Moreover, the resin component of the resin powder obtained comes into contact with hot air only instantaneously, and therefore, the resin component has almost no heat history and can be evaluated as being in a state corresponding to A-stage.

### Third Embodiment

(1) Resin Powder

Resin powder of the present embodiment (hereinafter referred to as resin powder) includes aggregates of spherical particles of a resin composition and nanofiller. The resin composition contains a resin component and a non-resin component (in the present embodiment, electrically insulative inorganic particles and/or magnetic particles). Detailed description of components similar to those in the first and second embodiments is omitted below.

(1.1) Resin Composition

(1.1.1) Nanofiller

The nanofiller is not particularly limited, and examples of the nanofiller include silica, alumina, ferrite, zeolite, titanium oxide, and a pigment such as carbon black.

The content of the nanofiller is preferably greater than or equal to 0.1 wt. % and less than or equal to 2 wt. % with respect to the resin powder. When the content of the nanofiller is within the above-described range, the fluidity of the resin powder can be improved. The upper limit of the content of the nanofiller is more preferably less than or equal to 1 wt. %, much more preferably less than or equal to 0.5 wt. %.

The mean particle size of the nanofiller is accordingly selected in accordance with the applications and the like of the resin powder. The upper limit of the mean particle size of the nanofiller is preferably 150 nm, more preferably 100 nm. The lower limit of the mean particle size of the nanofiller is preferably 1 nm, more preferably 10 nm. When the mean particle size of the nanofiller is within the above-described range, the fluidity of the resin powder can be improved. The mean particle size of the nanofiller refers to a particle size at an integrated value of 50% in particle size distribution measured based on a particle size distribution measurement device based on a laser scattering/diffraction method.

Examples of an index of the fluidity of the resin powder include an angle of repose. The angle of repose is the largest angle of a slope on which a stack of resin powder maintains stability without spontaneously collapsing. Specifically, the angle of repose is obtainable in a similar manner to the method described in the examples. As the angle of repose decreases, the fluidity of the powder increases. The packing efficiency is also improved.

The angle of repose of the resin powder is preferably smaller than or equal to 26°, more preferably smaller than or equal to 25.5°, much more preferably smaller than or equal to 25°. The lower limit of the angle of repose of the resin powder is preferably larger than or equal to 20°, more preferably larger than or equal to 21°, much more preferably larger than or equal to 22°.

(1.1.2) Non-Resin Component and Resin Component

The non-resin component and the resin component are common with those in the first embodiment or the second embodiment.

(1.2) Applications of Resin Powder

Use of the resin powder is not particularly limited, but the resin powder may be used in, for example, an electronic component. The electronic component includes a molded body of the resin powder. The electronic component is not particularly limited, but examples of the electronic component include a transistor, a diode, capacitor, a resistor, an inductor (coil), and a connector.

(2) Resin Powder Manufacturing Method

(2.1) Preparation of Slurry and Granulation by Spray-Dry Method Preparation of slurry and granulation by a spray-dry method are common to those in the first embodiment or the second embodiment.

(2.2) Addition of Nanofiller

The resin powder is obtained by obtaining dried powder by the spray-dry method and adding nanofiller to the dried powder. Between spherical particles of the resin composition, the nanofiller which are smaller than the spherical particles are provided, and thereby, the fluidity of the resin powder is further improved as compared the first embodiment and the second embodiment. Moreover, handleability is also improved.

<Variations>

The resin powder of the first embodiment may further include magnetic particles.

The resin powder of the second embodiment may further contain electrically insulative inorganic particles.

A sealing material containing the resin powder of any one of the first to third embodiments can seal electronic components other than the semiconductor element.

The present disclosure will be specifically described below with reference to examples, but the present disclosure is not limited to the following examples.

Raw materials for the slurry are shown below.

[Electrically Insulative Inorganic Particles]

Spherical alumina (“DAW-07”, D50: 8 μm; manufactured by Denka Company Limited)

### [Magnetic Particles]

Magnetic powder (“27 μm-product”, particle size: 27 μm-product; manufactured by EPSON ATMIX Corporation)

### [Resin Component]

### (Epoxy Resin)

Bisphenol A liquid epoxy resin (“EPICLON 850S” manufactured by DIC Corporation)

Biphenyl-aralkyl type epoxy resin (“NC-3000” manufactured by Nippon Kayaku Co., Ltd.) (Imide Resin)

Bismaleimide (“BMI-2300”, melting point: 70 to 145° C.; manufactured by Daiwa Kasei Industry Co., Ltd.)

Bis-allyl-nadi-imide (“BANI-M”, melting point: 75° C.; manufactured by Maruzen Petrochemical CO, LTD.) (curing agent)

Dicyandiamide (“Dicyandiamide” manufactured by Nippon Carbide Industries Co., Inc.) (Hardening Accelerator)

2-ethyl-4-methylimidazole (“2E4MZ” manufactured by Shikoku Chemicals Corporation) (Coupling Agent)

Epoxy silane (“A187” manufactured by Momentive Performance Materials Japan LLC) (Nanofiller)

Nanosilica (“YA050C-SM1”, particle size: 50 nm; manufactured by Admatechs Company Limited) The particle shape and a measurement method of the particle size distribution, the metal content, the acetone insoluble component, and the remaining solvent amount in the resin powder will be described below.

[Particle Shape]

The particle shape of the resin powder was evaluated by obtaining the average aspect ratio and the average circularity of the resin powder and based on the following criteria. The average aspect ratio and the average circularity of the resin powder are obtained by measuring the aspect ratio and the circularity of each particle with a particle image analyzer (“Morphologi G3” manufactured by Malvern Instruments Ltd, the same applies to the following description) and based on the average value of the measured values. The device measures the physical properties of a sample by uniformly dispersing the sample with an automated dry-dispersion unit and analyzing a still image of the sample.

When the average aspect ratio is greater than or equal to 0.80 and the average circularity is greater than or equal to 0.90, the particle shape of the resin powder was evaluated as being “spherical”. When neither the average aspect ratio nor the average circularity fails to satisfy the above-described condition, the particle shape of the resin powder was evaluated as being “variable shape”.

[Particle Size Distribution]

The particle size distribution of the resin powder is evaluated by obtaining the volume particle size distribution of the resin powder and based on the following criteria. The volume particle size distribution of the resin powder was measured with a particle image analyzer.

When in the volume particle size distribution, the ratio of the spherical particles whose particle size is larger than or equal to 50 μm and smaller than or equal to 100 μm is greater than or equal to 80 wt. % with respect to the resin powder, the particle size distribution of the resin powder was evaluated as being “sharp”. When the ratio of the spherical particles whose particle size is larger than or equal to 50 μm and smaller than or equal to 100 μm fails to satisfy the above-described condition, the particle size distribution was evaluated as being “broad”.

[Metal Foreign Substance]

The metal foreign substance of the resin powder was evaluated based on the following criteria. The metal content of the resin powder was obtained by inductively coupled plasma mass spectrometry (ICP/MS). When the metal content thus obtained is less than or equal to 1 ppm with respect to the resin powder, the metal foreign substance of the resin powder was evaluated as being “absent”. When the metal foreign substance thus obtained is greater than 1 ppm with respect to the resin powder, the metal content in the resin powder was evaluates as being “present”.

[Acetone Insoluble Component]

The acetone insoluble component of the resin powder was evaluated based on the following criteria. First, 300 g of resin powder were dissolved in acetone, were filtered with a 100-mesh metallic gauze to extract an insoluble component. A residual substance was dropped onto powder paper, which was weighed and divided by the initial mass, which is 300 g, of the resin, thereby computing the acetone insoluble amount (ppm). When the acetone insoluble amount thus obtained to the resin powder is less than or equal to 1 ppm with respect to the resin powder, the acetone insoluble component of the resin powder was evaluated as being “absent”. When the acetone insoluble amount thus obtained is greater than 1 ppm with respect to the resin powder, the acetone insoluble component in the resin powder was evaluates as being “present”.

[Remaining Solvent Amount]

The remaining solvent amount of the resin powder was measured as described below. The resin powder whose weight corresponds to 5 g was put in a dryer at 163° C./15 minutes, thereby removing a volatile matter content (solvent). A mass reduction of the resin powder was measured by measuring the mass of the resin powder before and after the resin powder was put in the dryer. The mass reduction with respect to the mass of the resin powder before the resin powder was put in the dryer was computed as the remaining solvent amount.

[Angle of Repose]

The angle of repose was measured as described below. First, 6 g of resin powder were put in a test tube (outer diameter: 12 mm, inner diameter: 10 mm, length: 120 mm). Next, an opening of the test tube was closed with a flat plate, and in this state, the test tube was turned upside down and was placed on a horizontal substrate. Then, the flat plate was horizontally slide and removed, and the test tube was slowly lifted vertically. Thereafter, based on the diameter and the height of conus sediment of resin powder spilled out of the test tube, the base angle of the conus sediment was computed, and the base angle was defined as the angle of repose.

### Example 1-1 and Example 1-7

Slurry was obtained by mixing a resin composition obtained by blending components in accordance with the blending ratio shown in Table 1 with a solvent. The solvent used was a solvent (hereinafter referred to as a combined solvent) prepared such that the mass ratio (MEK/DMF) of methyl ethyl ketone (MEK, boiling point: 79° C.) to N,N-dimethyl formamide (DMF, boiling point: 153° C.) is (7/3). The content ratio of the solid content in the slurry was 92 wt. % with respect to the slurry.

The slurry thus obtained was spray dried, and dried powder thus obtained was collectively collected to obtain resin powder. The spray drying was performed with a spray dryer (“P260” manufactured by PRECI Co., spray method: rotary atomizer method, collection method: cyclone collection method) under driving conditions described below.

Rotation speed of a rotary atomizer: 20000 rpm

Slurry feed rate: 2 kg/hour
Hot air temperature (entrance temperature): 100° C.
Exhaust air temperature (outlet temperature): 60° C.

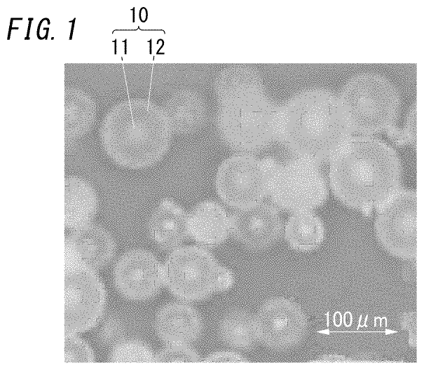

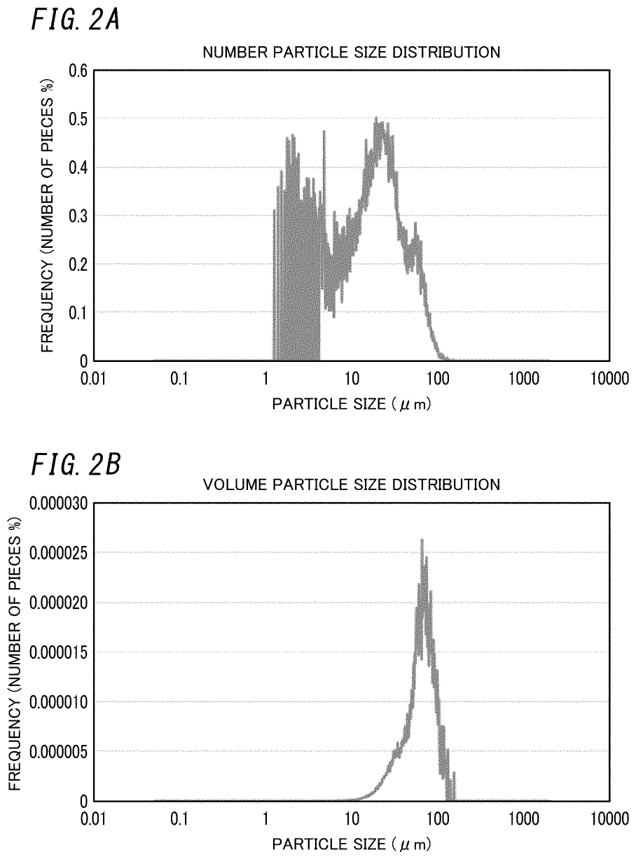

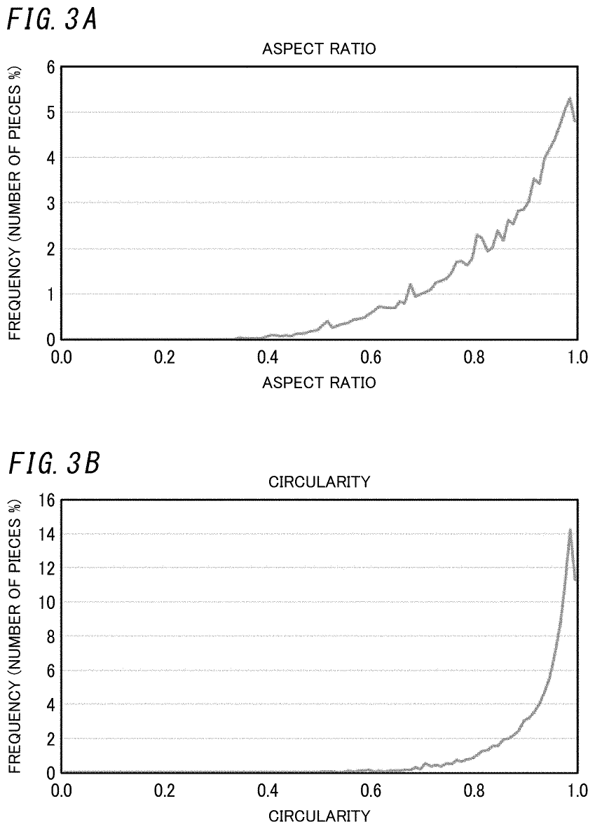

FIG. 1 is an SEM image (magnification: 100 times) of the resin powder obtained in Example 1-1, the SEM image being captured by a particle image analyzer. FIG. 2A is a graph illustrating number particle size distribution of the resin powder obtained in Example 1-1, the number particle size distribution being measured with the particle image analyzer. FIG. 2B is a graph of volume particle size distribution of the resin powder obtained in Example 1-1, the volume particle size distribution being measured with the particle image analyzer. FIG. 3A is a graph of an aspect ratio of the resin powder obtained in Example 1-1, the aspect ratio being measured with the particle image analyzer. FIG. 3B is a graph of circularity of the resin powder obtained in Example 1-1, the circularity being measured with the particle image analyzer.

From FIG. 1, it was confirmed that the particle 10 included in the resin powder of Example 1-1 is spherical. Moreover, from FIG. 1, it was confirmed that the spherical particle 10 includes a core 11 including at least one or more electrically insulative inorganic particles and a resin component 12 covering the entirety of the core 11. From FIG. 2A, it was confirmed that in the number particle size distribution, the resin powder has one frequency peak in each of a range in which the particle size is larger than or equal to 1 μm and smaller than or equal to 10 μm and a range in which the particle size is larger than 10 μm and smaller than or equal to 100 μm. From FIG. 2B, it was confirmed that the volume particle size distribution has one frequency peak.

The mean particle size of the resin powder obtained in Example 1-1 was 70 μm. The mean particle size of the resin powder is a median size (D50) of volume particle size distribution of the resin powder obtained in Example 1-1, the volume particle size distribution being measured with the particle image analyzer.

The average circularity of the resin powder obtained in Example 1-1 was 0.96. The average aspect ratio of the resin powder obtained in Example 1-1 was 0.86.

In the resin powder obtained in Example 1-1, the ratio of spherical particles whose particle size is larger than or equal to 50 μm and smaller than or equal to 100 μm in the volume particle size distribution was 81 wt. % with respect to the aggregates of the spherical particles. The mean particle size of the resin powder obtained in the Example 1-7 was obtained in a similar manner to Example 1-1 and was 65 μm.

### Example 1-2 to Example 1-6

Slurry was obtained by mixing a resin composition obtained by blending components (except for nanofiller) in accordance with the blending ratio shown in Table 1 with a combined solvent. In a similar manner to Example 1-1, slurry was spray dried, thereby obtaining dried powder. To the dried powder, the nanofiller was added in accordance with the blending ratio shown in Table 1 and were uniformly dispersed to obtain resin powder.

Example 1-2 to Example 1-6 are different from Example 1-1 only in that the nanofiller are included. Example 1-2 to Example 1-6 and Example 1-1 are under the same driving condition of the spray dryer. Therefore, the resin powder in each of Example 1-2 to Example 1-6 and the resin powder in Example 1-1 are assumed to be equivalent in terms of physical property evaluation of the particle shape, particle size distribution, and the like.

### Example 2-1

Slurry was obtained by mixing a resin composition obtained by blending components in accordance with the blending ratio shown in Table 1 with a combined solvent. The content ratio of the solid content in the slurry was 95 wt. % with respect to the slurry. The resin powder was obtained in a similar manner to Example 1-1 except that the slurry feed rate was 2.5 kg/hour.

The mean particle size of the resin powder obtained in Example 2-1 was 70 μm. The mean particle size of the resin powder is a median size (D50) of volume particle size distribution of the resin powder obtained in Example 2-1, the volume particle size distribution being measured with the particle image analyzer. The average circularity of the resin powder obtained in Example 2-1 was 0.95. The average aspect ratio of the resin powder obtained in Example 2-1 was 0.85.

The magnetic powder in Example 2-1 and the alumina particle in Example 1-1 are equivalent to each other in terms of the mean particle size. Example 2-1 and Example 1-1 are under the same driving condition of the spray dryer. Therefore, resin powder in Example 2-1 and the resin powder in Example 1-1 are assumed to be equivalent in terms of physical property evaluation of the particle shape, particle size distribution, and the like.

### Comparative Example 1-1

A resin composition obtained by blending components in accordance with the blending ratio shown in Table 1 and a combined solvent were put in a twin-shaft kneader and were kneaded at 100° C. However, the melting point of bismaleimide as a component of the resin composition is high, and thus, melt-kneading of the resin composition and the solvent was not possible.

### Comparative Example 1-2

A resin composition obtained by blending components in accordance with the blending ratio shown in Table 1 and a combined solvent were put in a twin-shaft kneader, were kneaded at 100° C. for 10 minutes, thereby obtaining a melt-kneaded product of the resin composition and the solvent. The kneaded product thus obtained was cooled and pulverized with a cutter mill, thereby obtaining resin powder. It was visually confirmed that the mean particle size of the resin powder obtained in Comparative Example 1-2 is obviously larger than 1 mm. The resin powder obtained in Comparative Example 1-1 was observed with a particle image analyzer, and the shape of the particles was angular fragment shape.

### Comparative Example 2-1

A resin composition obtained by blending components in accordance with the blending ratio shown in Table 1 and a combined solvent were put in a twin-shaft kneader, were kneaded at 100° C. for 15 minutes, thereby obtaining a melt-kneaded product of the resin composition and the solvent. The kneaded product thus obtained was cooled and pulverized with a cutter mill, thereby obtaining resin powder. It was visually confirmed that the mean particle size of the resin powder obtained in Comparative Example 2-1 is obviously larger than 1 mm.

TABLE 1

| | | | Product | | Example | | | | | |
|---|---|---|---|---|---|---|---|---|---|---|
| Contents | | | Number | Unit | 1-1 | 1-2 | 1-3 | 1-4 | 1-5 | 1-6 |
| Electrically | Alumina | Spherical | Daw-07 | parts by | 870 | 870 | 870 | 870 | 870 | 870 |
| Insulative | Particle | Alumina | | mass | | | | | | |
| Inorganic | | | | | | | | | | |
| Particle | | | | | | | | | | |
| Magnetic | Magnetic | Fe—3Si—5Cr | 27 | parts by | 0 | 0 | 0 | 0 | 0 | 0 |
| Particle | Powder | | μm-product | mass | | | | | | |
| Resin | Epoxy Resin | Bisphenol A | EPICLON | parts by | 0 | 0 | 0 | 0 | 0 | 0 |
| Component | | Liquid Epoxy | 850S | mass | | | | | | |
| | | Resin | | | | | | | | |
| | | Biphenyl-Aralkyl | NC-3000 | parts by | 0 | 0 | 0 | 0 | 0 | 0 |
| | | Type Epoxy Resin | | mass | | | | | | |
| | Imide Resin | Bismaleimide | BMI-2300 | parts by | 61.5 | 61.5 | 61.5 | 61.5 | 61.5 | 61.5 |
| | | | | mass | | | | | | |
| | | Bis-Allyl-Nadi-Imide | Bani-M | parts by | 66.8 | 66.8 | 66.8 | 66.8 | 66.8 | 66.8 |
| | | | | mass | | | | | | |
| | Hardener | Dicyandiamide | Dicyandiamide | parts by | 0 | 0 | 0 | 0 | 0 | 0 |
| | | | | mass | | | | | | |
| | Hardening | 2-Ethyl-4- | 2E4MZ | parts by | 0 | 0 | 0 | 0 | 0 | 0 |
| | Accelerator | Methylimidazole | | mass | | | | | | |
| | Coupling | Epoxy Silane | A187 | parts by | 1.74 | 1.74 | 1.74 | 1.74 | 1.74 | 1.74 |
| | Agent | | | mass | | | | | | |
| | Nanofiller | Nanosilica | YA050C-SM1 | parts by | 0 | 1 | 2 | 5 | 10 | 20 |
| | | | | mass | | | | | | |

| | | | | | | | | | |
|---|---|---|---|---|---|---|---|---|---|
| Measurement | Particle Shape | — | — | Spher- | Spher- | Spher- | Spher- | Spher- | Spher- |
| Result | | | | ical | ical | ical | ical | ical | ical |
| | Particle Size | — | — | Sharp | Sharp | Sharp | Sharp | Sharp | Sharp |
| | Distribution | | | | | | | | |
| | Metal Foreign | — | — | Absent | Absent | Absent | Absent | Absent | Absent |
| | Substance | | | | | | | | |
| | Acetone Insoluble | — | — | Absent | Absent | Absent | Absent | Absent | Absent |
| | Component | | | | | | | | |
| | Remaining Solvent | — | wt. % | 0 < 1 | 0 < 1 | 0 < 1 | 0 < 1 | 0 < 1 | 0 < 1 |
| | Amount * | | | | | | | | |
| | Angle of Repose | — | degree | 26.2 | 22.6 | 22.4 | 23 | 25.2 | 25.6 |

| | | | Product | | Example | | Comparative Example | | |
|---|---|---|---|---|---|---|---|---|---|
| Contents | | | Number | Unit | 1-7 | 2-1 | 1-1 | 1-2 | 2-1 |
| Electrically | Alumina | Spherical | Daw-07 | parts by | 870 | 0 | 870 | 870 | 0 |
| Insulative | Particle | Alumina | | mass | | | | | |
| Inorganic | | | | | | | | | |
| Particle | | | | | | | | | |
| Magnetic | Magnetic | Fe—3Si—5Cr | 27 | parts by | 0 | 870 | 0 | 0 | 870 |
| Particle | Powder | | μm-product | mass | | | | | |
| Resin | Epoxy Resin | Bisphenol A | EPICLON | parts by | 42.9 | 42.9 | 0 | 42.9 | 42.9 |
| Component | | Liquid Epoxy | 850S | mass | | | | | |
| | | Resin | | | | | | | |
| | | Biphenyl-Aralkyl | NC-3000 | parts by | 79.7 | 79.7 | 0 | 79.7 | 79.7 |
| | | Type Epoxy Resin | | mass | | | | | |
| | Imide Resin | Bismaleimide | BMI-2300 | parts by | 0 | 0 | 61.5 | 0 | 0 |
| | | | | mass | | | | | |
| | | Bis-Allyl-Nadi-Imide | Bani-M | parts by | 0 | 0 | 66.8 | 0 | 0 |
| | | | | mass | | | | | |
| | Hardener | Dicyandiamide | Dicyandiamide | parts by | 5.5 | 5.5 | 0 | 5.5 | 5.5 |
| | | | | mass | | | | | |
| | Hardening | 2-Ethyl-4- | 2E4MZ | parts by | 0.16 | 0.16 | 0 | 0.16 | 0.16 |
| | Accelerator | Methylimidazole | | mass | | | | | |
| | Coupling | Epoxy Silane | A187 | parts by | 1.74 | 1.74 | 1.74 | 1.74 | 1.74 |
| | Agent | | | mass | | | | | |
| | Nanofiller | Nanosilica | YA050C-SM1 | parts by | 0 | 0 | 0 | 0 | 0 |
| | | | | mass | | | | | |

| | | | | | | | | |
|---|---|---|---|---|---|---|---|---|
| Measurement | Particle Shape | — | — | Spher- | Spher- | Indef- | Indef- | Indef- |
| Result | | | | ical | ical | inite | inite | inite |
| | Particle Size | — | — | Sharp | Sharp | Broad | Broad | Broad |
| | Distribution | | | | | | | |
| | Metal Foreign | — | — | Absent | Absent | Present | Present | Present |
| | Substance | | | | | | | |
| | Acetone Insoluble | — | — | Absent | Absent | Present | Present | Present |
| | Component | | | | | | | |
| | Remaining Solvent | — | wt. % | 0 < 1 | 0 < 1 | 0 | 0 | 0 |
| | Amount * | | | | | | | |
| | Angle of Repose | — | degree | — | — | — | — | — |

* “0 < 1” means that the remaining solvent amount is greater than 0 wt. % and less than 1 wt. %.

[Bulkiness of Resin Powder]

The bulkiness of the resin powder was evaluated based on the following criteria.

First, a sample 20 was prepared by weighing 6 g of resin powder (specific gravity: 3 g/cm³) obtained in Example 1-1, and a sample 30 was prepared by weighing 4 g of resin powder (specific gravity: 2 g/cm³) obtained in Comparative Example 1-2 such that the sample 20 and the sample 30 have the same volume. FIG. 6A is an image of the sample 20 in Example 1-1. FIG. 6B is an image of the sample 30 in Comparative Example 1-1.

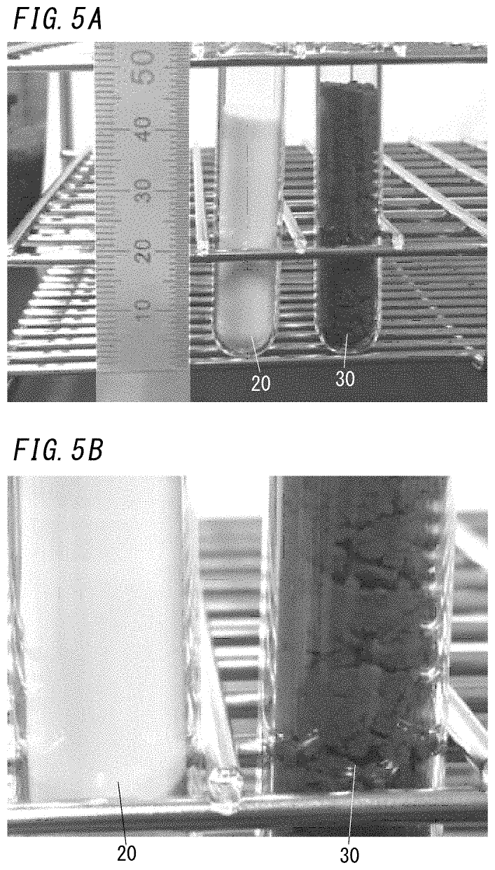

The sample 20 and the sample 30 were put in different test tubes (outer diameter: 12 mm, inner diameter: 10 mm, length: 120 mm), and then, the bottom surfaces of the test tubes were tapped three times so that powder attached to the side surface of each test tube lightly falls off. FIG. 5A is an image of the sample 20 in the test tube in Example 1-1 and the sample 30 in the test tube in Comparative Example 1-2 after the bottom surfaces were tapped three times. FIG. 5B is an enlarged image of the sample 20 in the test tube in Example 1-1 and the sample 30 in the test tube in Comparative Example 1-2 of FIG. 5A, wherein in FIGS. 5A and 5B, the sample on the left is the sample 20 in Example 1-1, and the sample on the right is the sample 30 in Comparative Example 1-2.

The height of each sample from the bottom surface of the test tube was measured with a scale, and the height of the sample 20 in Example 1-1 was 44 mm, and the height of the sample 30 in Comparative Example 1-2 was 48 mm. As can be seen from FIG. 5B, filling density of the sample 20 in Example 1-1 is higher than the filling density of the sample 30 in the Comparative Example 1-2. From these results, the sample 30 in Comparative Example 1-2 is evaluated as being bulkier than the sample 20 in Example 1-1. Thus, it was found that the sample 20 in Example 1-1 is easily uniformly put in the cavity formed in the mold as compared to the sample 30 in Comparative Example 1-2. Moreover, the smaller the diameter of the test tube, the more significant an evaluation difference of the bulkiness between the sample 20 in Example 1-1 and the sample 30 in Comparative Example 1-2. That is, the example 20 in Example 1-1 is filled in a gap smaller than a gap willed with the sample 30 in Comparative Example 1-2.

### REFERENCE SIGNS LIST

10 Spherical Particle of Resin Composition
11 Core Including at Least One or More Electrically Insulative Inorganic Particles
12 Resin Component
20 Sample Obtained in Example 1-1
30 Sample Obtained in Comparative Example 1-2

1. Resin powder comprising aggregates of spherical particles of a resin composition,
the resin composition containing:
a resin component including a thermosetting resin; and
a non-resin component including at least one electrically insulative inorganic particle and/or at least one magnetic particle.

2. The resin powder of claim 1, wherein
each of the spherical particles includes
a core including the at least one electrically insulative inorganic particle and the resin component covering the core.

3. The resin powder of claim 1, wherein
each of the spherical particles includes
a core including the at least one magnetic particle and the resin component covering the core.

4. The resin powder of claim 1, wherein
in volume particle size distribution, a mean particle size of the resin powder is larger than or equal to 10 μm and smaller than or equal to 200 μm.

5. The resin powder of claim 1, wherein
in the volume particle size distribution, a ratio of the spherical particles whose particle size is larger than or equal to 50 μm and smaller than or equal to 100 μm to the resin powder is greater than or equal to 70 wt. %.

6. The resin powder of claim 1, wherein
the volume particle size distribution has one frequency peak.

7. The resin powder of claim 1, wherein
an average circularity of the aggregates is greater than or equal to 0.90 and less than or equal to 1.00.

8. The resin powder of claim 1, wherein
the resin component is in an uncured state.

9. The resin powder of claim 1, wherein
the resin powder further contains nanofiller.

10. The resin powder of claim 9, wherein
a content of the nanofiller is greater than or equal to 0.1 wt. % and less than or equal to 2 wt. % with respect to the resin powder.

11. The resin powder of claim 9, wherein
a mean particle size of the nanofiller is larger than or equal to 1 nm and smaller than or equal to 150 nm.

12. The resin powder of claim 1, wherein
an angle of repose of the resin powder is smaller than or equal to 26°.

13. A sealing material comprising the resin powder of claim 1.

14. An electronic component comprising a molded body containing the resin powder of claim 1.

15. A resin powder manufacturing method comprising:
preparing slurry containing
a resin component including a thermosetting resin and
a non-resin component including at least one electrically insulative inorganic particle and/or at least one magnetic particle; and
granulating the slurry by a spray-dry method.

16. The resin powder manufacturing method, comprising:
adding nanofiller to resin powder obtained by the method of claim 15.
